(19) United States
(12) Patent Application Publication
(10) Pub. No.: US 2016/0054382 A1
(43) Pub. Date: Feb. 25, 2016

(54) METHOD FOR CHECKING RESULT OF CHIP PROBING TEST AND CHIP THEREOF

(71) Applicant: NANYA TECHNOLOGY CORPORATION, Tao-Yuan Hsien (TW)

(72) Inventor: Wen-Ming LEE, Miaoli County (TW)

(21) Appl. No.: 14/465,842

(22) Filed: Aug. 22, 2014

(51) Int. Cl. G01R 31/28

(52) U.S. Cl. CPC G01R 31/2851

(57) ABSTRACT

A chip having information of a result of a chip probing test and a method for checking the results of the chip probing test are disclosed. The chip includes a chip substrate and a record module located on the chip substrate. The record module is configured to record a status code indicating whether the chip passes the chip probing test. The method includes following steps: executing the chip probing test for the chip; and recording the status code in the record module of the chip, the status code indicating whether the chip passes the chip probing test.

### BACKGROUND

1. Field of Invention

The present disclosure relates to semiconductor fabrication. More particularly, the present disclosure relates to a wafer test process in the semiconductor fabrication.

2. Description of Related Art

In recent years, multi-chip package techniques for incorporating several memory chips into a single package have been widely used to increase memory capacity. However, when a failure happens, it is difficult to check whether the chip passed the former chip probing test efficiently. A traditional solution is to read out chip information such as a lot number, a wafer number, and coordinates on a wafer from chip identification (chip ID) and then contact chip makers to request corresponding testing log files, which is very inconvenient for testers.

### SUMMARY

One aspect of the present disclosure is related to a chip having information of a result of a chip probing test. In an embodiment of the present disclosure, the chip includes a chip substrate and a record module located on the chip substrate. The record module is configured to record a status code indicating whether the chip passes the chip probing test.

Another aspect of the present disclosure is a method for checking the result of the chip probing test. In an embodiment of the present disclosure, the method includes following steps: executing the chip probing test for the chip; and recording the status code in the record module of the chip, the status code indicating whether the chip passes the chip probing test.

In summary, through the application of the aforementioned embodiments, by recording information of the result of the chip probing test in the record module of the chip, users can easily check whether the chip passes the chip probing test efficiently without contacting chip makers to request corresponding testing log files.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a diagram illustrating a chip according to an embodiment of the present disclosure;

FIG. 2 is a diagram illustrating a record process according to an embodiment of the present disclosure;

FIG. 3 is a diagram illustrating a checking process according to an embodiment of the present disclosure;

FIG. 4 is a diagram illustrating a chip according to an embodiment of the present disclosure;

FIG. 5 is a diagram illustrating a record process according to an embodiment of the present disclosure;

FIG. 6 is a flowchart illustrating a checking method according to an embodiment of the present disclosure;

FIG. 7 is a flowchart illustrating a checking method according to an embodiment of the present disclosure.

### DETAILED DESCRIPTION

Reference will now be made in detail to embodiments of the present disclosure, examples of which are described herein and illustrated in the accompanying drawings. While the disclosure will be described in conjunction with embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. The size ratio between elements in the drawings is only used for understanding, and not meant to limit the actual embodiments of the present disclosure in scale. Wherever possible, the same reference numbers are used in the drawings and the description to refer to the same or like parts for better understanding.

The terms used in this specification and claim, unless otherwise stated, generally have their ordinary meanings in the art, within the context of the disclosure, and in the specific context where each term is used. Certain terms that are used to describe the disclosure are discussed below, or elsewhere in the specification, to provide additional guidance to the practitioner skilled in the art regarding the description of the disclosure.

The terms “about” and “approximately” in the article are used as equivalents. Any numerals used in this article with or without about/approximately are meant to cover any normal fluctuations appreciated by one of ordinary skill in the relevant art. In certain embodiments, the term “approximately” or “about” refers to a range of values that fall within 20%, 10%, 5%, or less in either direction (greater than or less than) of the stated reference value unless otherwise stated or otherwise evident from the context.

The terms “first,” “second,” . . . etc., in the article do not refer to any specific order, or intended to limit the present disclosure, it is only used for distinguishing the differences between components or operations with the same technological descriptions.

In the following description and in the claims, the terms “include” and “comprise” are used in an open-ended fashion, and thus should be interpreted to mean “include, but not limited to . . . ”.

Also, the term “coupled” or “connected” may refer to two or more elements are in direct physical or electrical contact, or in indirect physical or electrical contact via other devices and connections, and may also refer to two or more elements cooperate or interact with each other.

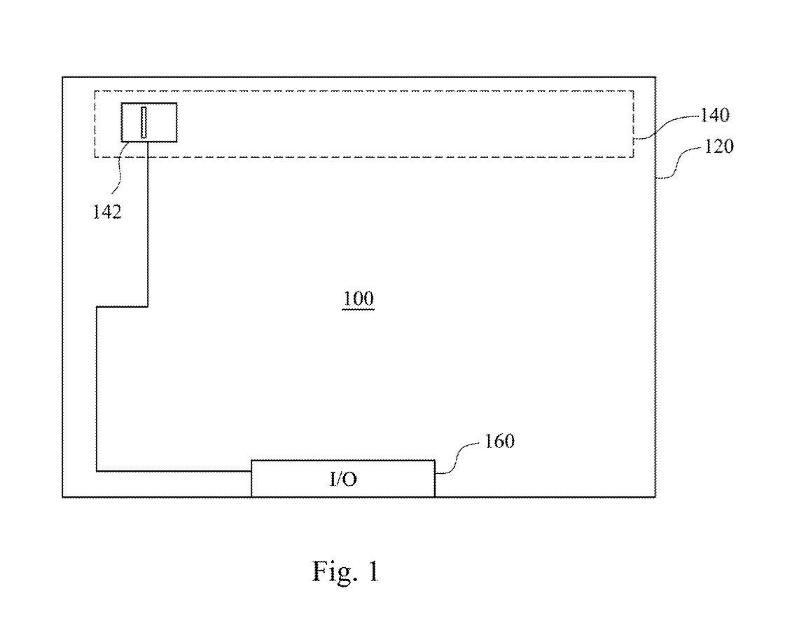

FIG. 1 is a diagram illustrating a chip 100 according to an embodiment of the present disclosure. As shown in FIG. 1, the chip 100 includes a chip substrate 120 and a record module 140 located on the chip substrate 120. The record module 140 is configured to record a status code SC indicating whether the chip 100 passed the chip probing test. For example, the status code SC may be configured to a first predetermined value (e.g., 1) if the chip 100 passed the chip probing test and may be configured to a second predetermined value (e.g., 0) if the chip 100 failed in the chip probing test.

In the present embodiment, the record module 140 includes a fusible part 142 representing a binary value to record the status code SC. For example, if the status code SC is configured to be 1 (i.e., the chip passed the test), the fusible part 142 is configured to be un cut; on the other hand, if the status code SC is configured to be 0 (i.e., the chip failed in the test), the fusible part 142 is configured to be fused and cut off. Therefore, the information of the result of the chip probing test is recorded on the chip 100 to be read out when necessary.

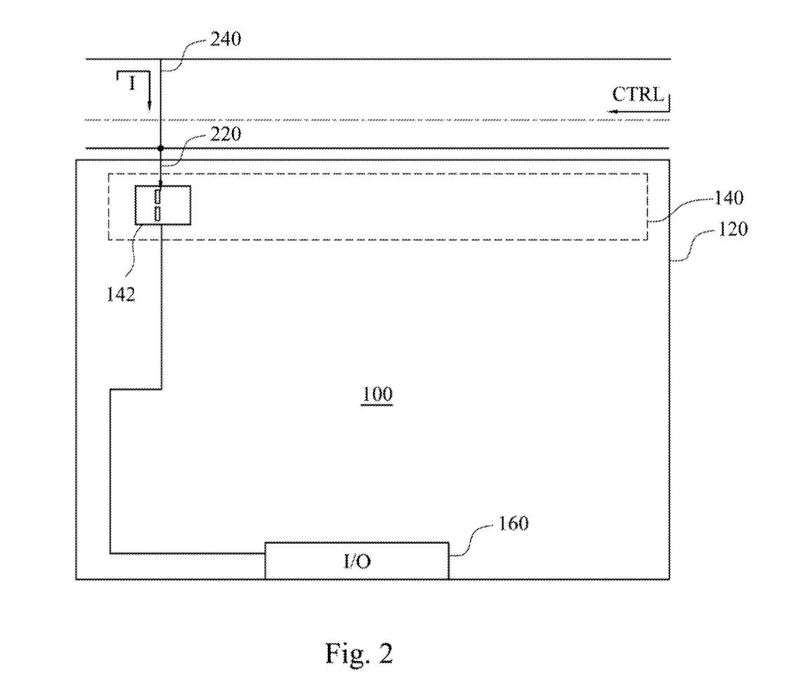

FIG. 2 is a diagram illustrating the aforementioned recording process according to an embodiment of the present disclosure. The recording process may be implemented with a probe 220 in the chip probing test. A control signal CTRL is configured to control a switch 240 electrically coupled to the probe 220. When the control signal CTRL is configured to be ON, the switch 240 is configured to be short and current I may pass through the probe 220 and cut off the fusible part 142, indicating the status code SC is configured to be 0 (i.e., the chip failed in the test.) On the other hand, when the control signal CTRL is configured to be OFF, the switch 240 is configured to be open and the fusible part 142 is remain uncut, indicating the status code SC is configured to be 1 (i.e., the chip passed the test.)

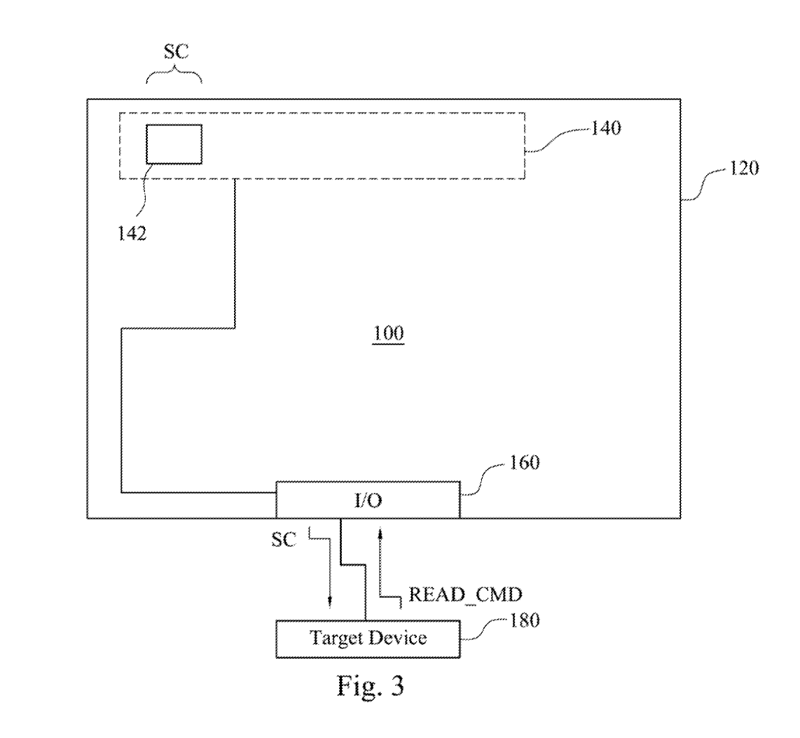

Referring to FIG. 3, in an embodiment of the present disclosure, the chip 100 may further include a transfer interface 160 located on the chip substrate 120, electrically coupled to the record module 140, and configured to communicate with a target device 180 to provide the information of the result of the chip probing test through a checking process.

For example, in an embodiment of the present disclosure, the transfer interface 160 may receive a read command signal READ_CMD from the target device 180 and may output the status code SC corresponding to the read command signal READ_CMD.

Specifically, in the checking process according to the present embodiment, the transfer interface 160 is first configured to keep monitoring whether the read command signal READ_CMD is received when the chip 100 is connected to the target device 180. When the read command signal READ_CMD is received, the transfer interface 160 is configured to read out the status code SC recorded in the fusible part 142 of the record module 140, and to output the status code SC to the target device 180 after few cycles. The target device 180 may be configured to receive the status code SC from the chip 100, and an user may then know whether the chip 100 passed the chip probing test according to the status code SC received by the target device 180.

In another embodiment, the transfer interface 160 may output an error signal ERR to the target device 180 when the target device 180 is connected to the chip 100, if the status code SC recorded in the record module 140 indicates the chip 100 failed in the test, and the user may then know the chip 100 failed in the chip probing test according to the error signal ERR received by the target device 180.

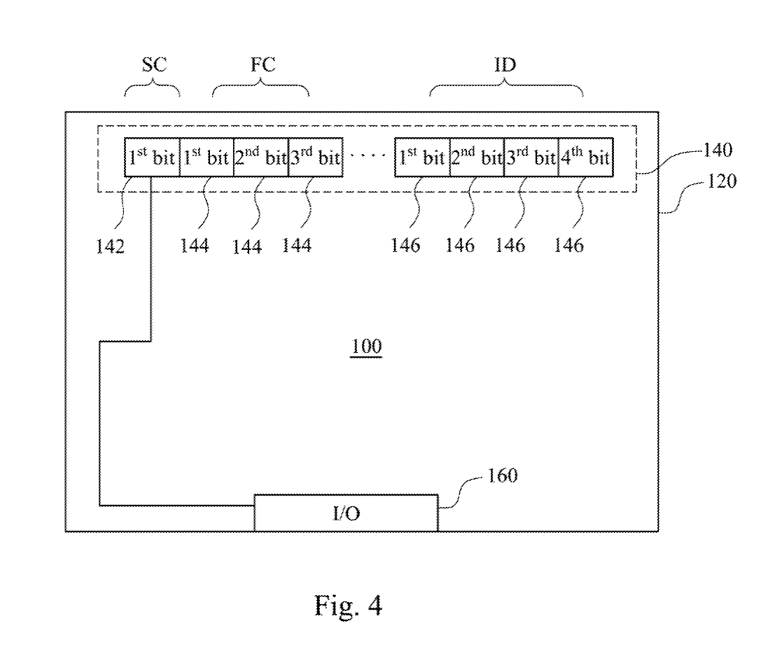

FIG. 4 is a diagram illustrating the chip 100 according to another embodiment of the present disclosure. In the present embodiment, the record module 140 may include the fusible part 142 and may further include N fusible parts 144, in which N is a positive integer. Each of the fusible part 144 represents a binary digit to record a bit in a failure code FC. The failure code FC is configured to indicate a test pattern that the chip 100 failed in the chip probing test, in the case that the chip 100 failed in the chip probing test. N fusible parts 144 may be configured to indicate the failure code FC with N-bits.

In the present embodiment, the failure code FC for the chip 100 may indicate the corresponding test patterns that the chip 100 failed. For example, if the chip 100 is a memory chip, the corresponding test patterns may include a stuck at fault (SAF), a transition fault (TF), a coupling fault (CF), a neighborhood pattern sensitive fault (NPSF), an address decoding fault (AF), etc. If the transition fault (TF) is the test pattern that the chip 100 failed in the chip probing test, the failure code FC may be configured to be “TF”, or “01010100 01000110” in a binary number with 16 bits indicating the transition fault (TF).

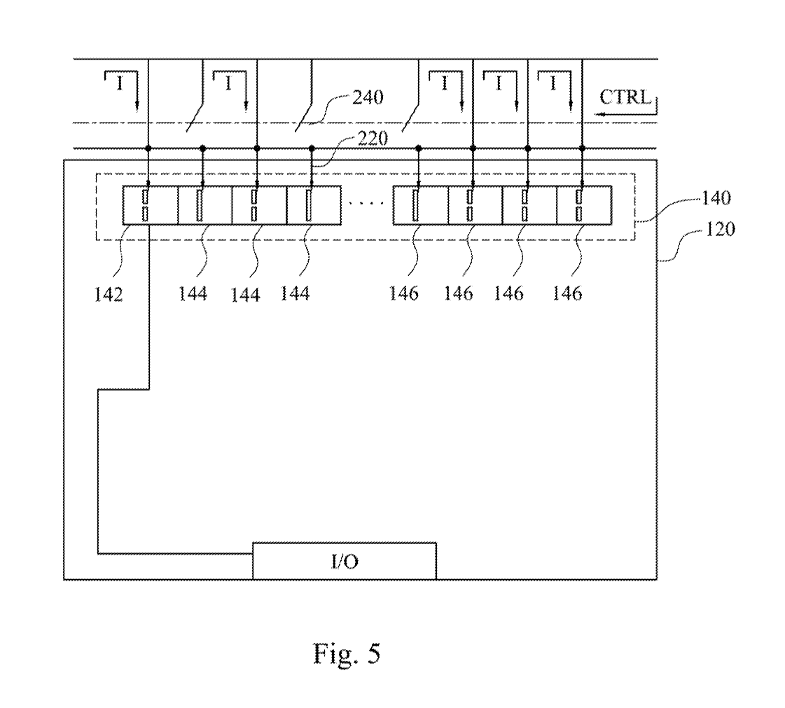

FIG. 5 is a diagram illustrating the recording process according to the present embodiment. Similar to the embodiment mentioned above, the recording process may be implemented with the probes 220 in the chip probing test. The control signal CTRL is configured to control the switches 240 electrically coupled to the probes 220. The control signal CTRL may switch between ON and OFF in different clock cycles, and in each clock cycle the control signal CTRL is configured to be ON or OFF depending on the binary value to be recorded on the corresponding fusible part 142 or fusible part 144.

Specifically, in an embodiment, when the control signal CTRL is ON in this clock cycle, the corresponding switch 240 is configured to be short and current I may pass through the corresponding probe 220 and cut off the corresponding fusible part 142 or fusible part 144, indicating the corresponding bit of the status code SC or the failure code FC is configured to be 0. On the other hand, when the control signal CTRL is OFF in this clock cycle, the corresponding switch 240 is configured to be open and the corresponding fusible part 142 or fusible part 144 is remain uncut, indicating the corresponding bit of the status code SC or the failure code FC is configured to be 1.

That is to say, if the Kth-bit of the failure code FC is configured to be 1, the Kth-stage fusible part 144 is not cut off; on the other hand, if the Kth-bit of the failure code FC is configured to be 0, the Kth-stage fusible part 144 is fused and cut off, in which K is a positive number no larger than N. Therefore, the information of the result of the chip probing test with more details is recorded on the chip to be read out when necessary.

Similar to the embodiment mentioned above, in the present embodiment, the information of the result of the chip probing test with more details may be read out when the read command signal READ_CMD is received. The transfer interface 160 is configured to read out the status code SC and the failure code FC recorded in the record module 140 after few cycles. The user may then know whether the chip 100 passed the chip probing test, and the test pattern the chip 100 failed in the chip probing test (in the case that the chip 100 failed in the chip probing test) according to the status code SC and the failure code FC received by the target device 180.

Likewise, the transfer interface 160 may also output the error signal ERR to the target device 180 connected to the chip 100 according to the status code SC and the failure code FC recorded in the record module 140, and the user may then know the chip 100 failed in the chip probing test according to the error signal ERR received by the target device 180.

Again referring to FIG. 5, the record module 140 may further include N fusible parts 146, in which N is a positive integer. Each of the fusible part 146 represents a binary digit to record a bit in a chip identification code ID indicating chip identification such as a lot number, a wafer number, etc. N fusible parts 146 may be configured to indicate the chip identification code ID with N-bits. The recording process of the chip identification code ID is similar to the recording process of the status code SC and of the failure code FC disclosed above, and is omitted herein for the sake of brevity.

The record module 140 mentioned in the embodiments disclosed above may be implemented by a non-volatile memory. For example, the record module 140 may be a one-time programmable non volatile memory. The fusible part 142 may be implemented by the same material used in chip manufacturing process, such as polysilicon, aluminum, copper, tungsten, etc.

The techniques disclosed in the present embodiment may be applied to chips using multi-chip package technologies, such as a dynamic random-access memory (DRAM) chip.

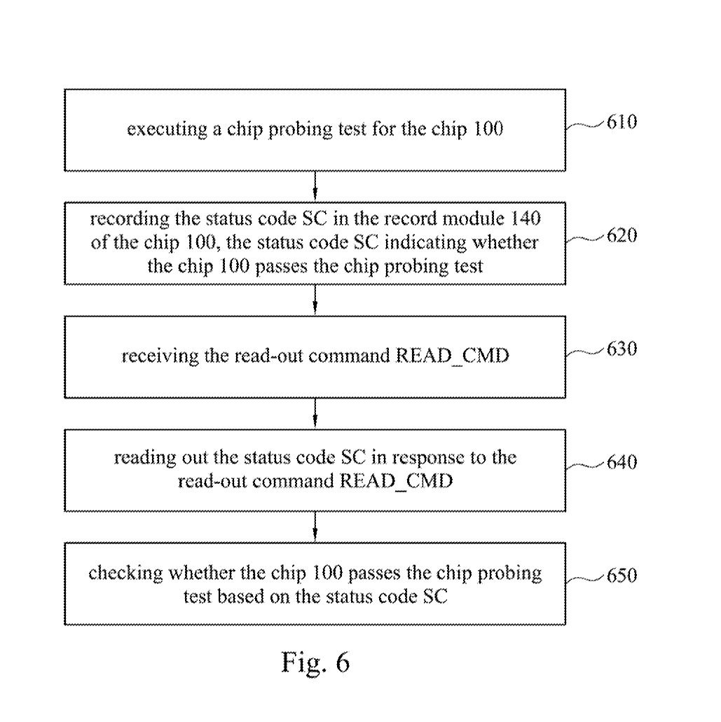

FIG. 6 is a flowchart illustrating a checking method according to an embodiment of the present disclosure. The method shown in FIG. 6 includes step 610 and 620. In step 610, the chip probing test is executed for the chip 100. In step 620, the status code SC is recorded in the record module 140 of the chip 100 indicating whether the chip 100 passes the chip probing test.

The method for checking the result of the chip probing test may further include step 630, 632, and 634. In step 630, the read-out command READ_CMD is received. In step 632, the status code SC is read out in response to the read-out command READ_CMD. In step 634, whether the chip 100 passes the chip probing test is checked based on the status code SC.

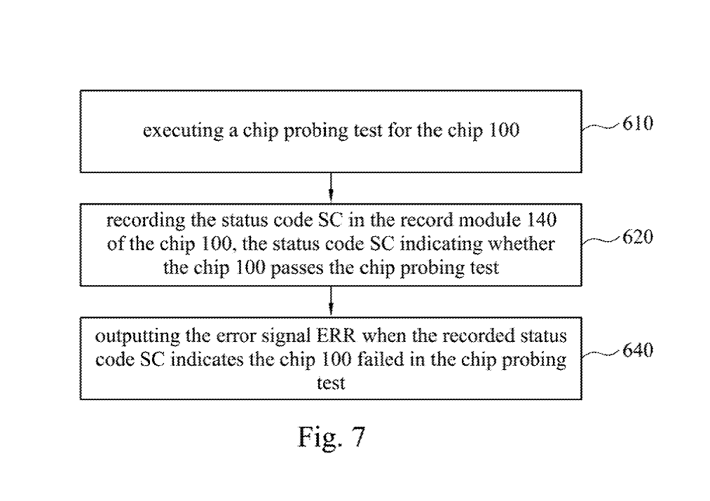

FIG. 7 is a flowchart illustrating the checking method according to another embodiment of the present disclosure. In the present embodiment, the method includes step 610, 620, and further includes step 640. In step 640, the error signal ERR is outputted when the recorded status code SC indicates the chip 100 failed in the chip probing test.

In an embodiment of the present disclosure, the method mentioned above may further include selectively supplying the current to corresponding part 142 of the record module 140 based on the recorded status code SC with the probes 220 used in the chip probing test, and selectively supplying the current to corresponding parts 146 of the record module 140 to record the chip identification code ID with the probes 220 used in the chip probing test. Because the recording steps mentioned above are both implemented with the probes 220 used in the chip probing test, it is possible to perform the recording steps together at the same time, or to perform the recording steps separately according to practical needs.

In another embodiment of the present disclosure, the method mentioned above may further include recording the failure code FC when the chip 100 failed in the chip probing test, and selectively supplying the current to corresponding parts 144 of the record module 140 based on the recorded failure code FC with probes 220 used in the chip probing test. Moreover, the method may further include outputting the error signal ES corresponding to the failure code FC when the recorded status code SC indicates the chip 100 failed in the chip probing test.

In the aforementioned embodiments, switches 240 may be implemented by bipolar junction transistors (BJTs), metal oxide semiconductor field effect transistors (MOSFETs), thin-film transistors (TFTs), or other kinds of transistors, which may be configured by those skilled in the art.

In summary, as disclosed in the embodiments mentioned above, by recording information of the result of the chip probing test in the record module 140 of the chip 100, users can easily check whether the chip 100 passed the chip probing test efficiently without contacting. chip makers to request corresponding testing log files.

Although the discourse has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A chip having information of a result of a chip probing test, comprising
a chip substrate; and
a record module located on the chip substrate, the record module being configured to record a status code, the status code indicating whether the chip passes the chip probing test.

2. The chip of claim 1, wherein a part of the record module is fusible to be cut with a current.

3. The chip of claim 1, wherein the record module is configured to further record a failure code configured to indicate a test pattern the chip failed in the chip probing test.

4. The chip of claim 1, further comprising:
a transfer interface located on the chip substrate and electrically coupled to the record module, configured to output the status code corresponding to a read command signal.

5. The chip of claim 1, further comprising:
a transfer interface located on the chip substrate and electrically coupled to the record module, configured to output an error signal when the status code indicates the chip failed in the chip probing test.

6. The chip of claim 1, wherein the record module is configured to further record a chip identification code.

7. The chip of claim 1, wherein the record module comprises a one-time programmable non volatile memory.

8. The chip of claim 1, wherein the chip is a dynamic random-access memory (DRAM) chip.

9. A method for checking a result of a chip probing test, comprising
executing a chip probing test for a chip; and
recording a status code in a record module of the chip, the status code indicating whether the chip passes the chip probing test.

10. The method of claim 9, further comprising:
receiving a read-out command;
reading out the status code in response to the read-out command; and
checking whether the chip passes the chip probing test based on the status code.

11. The method of claim 9, further comprising
outputting an error signal when the recorded status code indicates the chip failed in the chip probing test.

12. The method of claim 9, wherein a plurality of parts of the record module are fusible to be cut with a current, and the method further comprises:
selectively supplying the current to corresponding parts of the record module based on the recorded status code with probes used in the chip probing test.

13. The method of claim 12, further comprises:
selectively supplying the current to corresponding parts of the record module to record the status code and to record a chip identification code at the same time with probes used in the chip probing test.

14. The method of claim 12, further comprises:
selectively supplying the current to corresponding parts of the record module to record the status code after selectively supplying the current to corresponding parts of the record module to record a chip identification code with probes used in the chip probing test.

15. The method of claim 12, wherein the record module is further configured to record a failure code, and the method further comprises:
recording a failure code when the chip failed in the chip probing test, wherein the failure code indicates a test pattern that the chip failed in the chip probing test; and
selectively supplying the current to corresponding parts of the record module based on the recorded failure code with probes used in the chip probing test.

16. The method of claim 15, further comprising
outputting an error signal corresponding to the failure code when the recorded status code indicates the chip failed in the chip probing test.

17. The method of claim 9, wherein the record module comprises a one-time programmable non volatile memory.

18. The method of claim 9, wherein the chip is a dynamic random-access memory (DRAM) chip.
